(19) United States
(12) Patent Application Publication
(10) Pub. No.: US 2022/0200568 A1
(43) Pub. Date: Jun. 23, 2022

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Zhejiang (CN)

(21) Appl. No.: 17/419,651

(22) PCT Filed: Nov. 5, 2019
(86) PCT No.: PCT/CN2019/115649

§ 371 Date: Mar. 1, 2022

(30) Foreign Application Priority Data
Dec. 29, 2018 (CN) 201811643179.7

(51) Int. Cl. H03H 9/19; H03B 5/32

(52) U.S. Cl. CPC H03H 9/19; H01L 41/053; H03B 5/32

(57) ABSTRACT

A structure and method for integrating a crystal resonator with a control circuit are disclosed. The integration is accomplished by bonding a substrate containing an upper cavity to a device wafer containing both the control circuit and a lower cavity so that a piezoelectric vibrator is sandwiched between the device wafer and the substrate. An increased degree of integration of the crystal resonator and on-chip modulation of its parameters can be achieved by further bonding a semiconductor die to the device wafer. Compared to traditional ones, in addition to being able to integrate with other semiconductor components more easily with a higher degree of integration, the crystal resonator of the present invention is more compact in size and hence less power-consuming.

### TECHNICAL FIELD

The present invention relates to the field of semiconductor technology and, in particular, to a structure and method for integrating a crystal resonator with a control circuit.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, existing crystal resonators are not only hard to be integrated with other semiconductor components but also bulky themselves.

For example, commonly used existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an objective of the present invention to provide a method for integrating a crystal resonator with a control circuit, which overcomes the above described problems with conventional crystal resonators, i.e., a bulky size and difficult integration.

According to the present invention, the above objective is attained by a method for integrating a crystal resonator with a control circuit, including:

providing a device wafer having the control circuit formed therein;

forming, in the device wafer, a lower cavity with an opening at a back side of the device wafer;

providing a substrate and etching the substrate so that an upper cavity of the crystal resonator is formed therein, wherein the upper cavity is formed in opposition to the lower cavity;

forming a piezoelectric vibrator including a top electrode, a piezoelectric crystal and a bottom electrode, which are formed on either of the back side of the device wafer and the substrate;

forming a first connecting structure on the device wafer or on the substrate;

bonding the substrate to the back side of the device wafer such that the piezoelectric vibrator is situated between the device wafer and the substrate, with the upper cavity and the lower cavity being located on opposing sides of the piezoelectric vibrator, and with the first connecting structure electrically connecting both the top and bottom electrodes of the piezoelectric vibrator to the control circuit; and

bonding a semiconductor die to a front side of the device wafer and forming a second connecting structure, wherein the semiconductor die is electrically connected to the control circuit via the second connecting structure.

It is an objective of the present invention to provide a structure for integrating a crystal resonator with a control circuit, including:

a device wafer in which the control circuit and a lower cavity are formed, the lower cavity having an opening at a back side of the device wafer;

a substrate, which is bonded to the device wafer from the back side thereof, and in which an upper cavity is formed, the upper cavity having an opening arranged in opposition to the opening of the lower cavity;

a piezoelectric vibrator including a top electrode, a piezoelectric crystal and a bottom electrode, the piezoelectric vibrator arranged between the device wafer and the substrate so that the lower and upper cavities are on opposing sides of the piezoelectric vibrator;

a first connecting structure configured to electrically connect the top and bottom electrodes of the piezoelectric vibrator to the control circuit;

a semiconductor die bonded to a front side of the device wafer; and

a second connecting structure configured to electrically connect the semiconductor die to the control circuit.

In the provided method, planar fabrication processes are utilized to form the lower cavity in the device wafer containing the control circuit in such a manner that the lower cavity is exposed from the back side of the device wafer. In this way, the piezoelectric vibrator can be formed on the back side of the device wafer, achieving integration of the control circuit and the crystal resonator on the same device wafer. Moreover, the semiconductor die can be further bonded to the device wafer, resulting in an enhancement in performance of the crystal resonator by allowing on-chip modulation of its parameters (e.g., in order to correct raw deviations of the crystal resonator such as temperature and frequency drifts), in addition to a significant increase in the crystal resonator's degree of integration.

Therefore, compared with traditional crystal resonators (e.g., surface-mount ones), in addition to being able to integrate with other semiconductor components more easily with a higher degree of integration, the crystal resonator of the present invention is more compact or miniaturized in size and hence less costly and less power-consuming.

### BRIEF DESCRIPTION OF THE DRAWINGS

FIG. 1 shows a flowchart schematically illustrating a method for integrating a crystal resonator according to an embodiment of the present invention.

FIGS. 2a to 2n are schematic representations of structures resulting from steps in a method for integrating a crystal resonator according to an embodiment of the present invention.

FIGS. 3a to 3d are schematic representations of structures resulting from steps in a method for integrating a crystal resonator with a control circuit according to a third embodiment of the present invention.

FIG. 4 schematically illustrates a structure for integrating a crystal resonator with a control circuit according to an embodiment of the present invention.

In these figures,
100—device wafer; AA—device area; 100U—front side; 100D—back side; 100A—substrate wafer; 100B—dielectric layer; 110—control circuit; 111—first circuit; 111a—first interconnect; 111b—third interconnect; 112—second circuit; 112a—second interconnect; 112b—fourth interconnect; 120—lower cavity; 211a—first conductive plug; 212a—second conductive plug; 221a—first connecting wire; 222a—second connecting wire; 230—third conductive plug; 410—first plastic encapsulation layer; 420—second plastic encapsulation layer; 400—support wafer; 500—piezoelectric vibrator; 510—bottom electrode; 520—piezoelectric crystal; 530—top electrode; 600—planarized layer; 700—semiconductor die; 710—contact pad.

### DETAILED DESCRIPTION

The core idea of the present invention is to provide a structure and method for integrating a crystal resonator with a control circuit, in which planar fabrication processes are utilized to integrate the crystal resonator and an associated semiconductor die both on a device wafer where the control circuit is formed. This, on the one hand, results in a size reduction of the crystal resonator and, on the other hand, allows an increased degree of integration of the crystal resonator with other semiconductor components.

Specific embodiments of the structure and method proposed in the present invention will be described below in greater detail with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

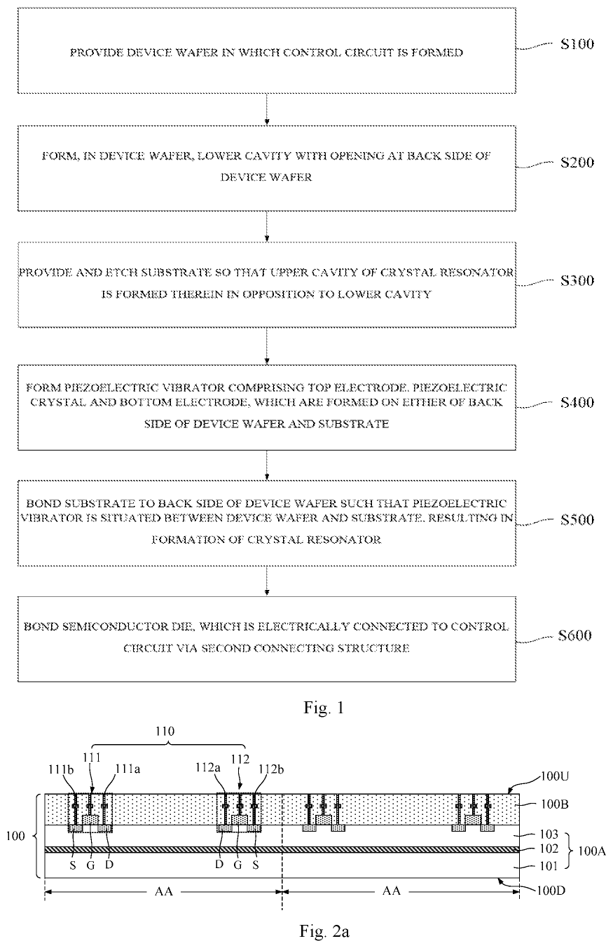

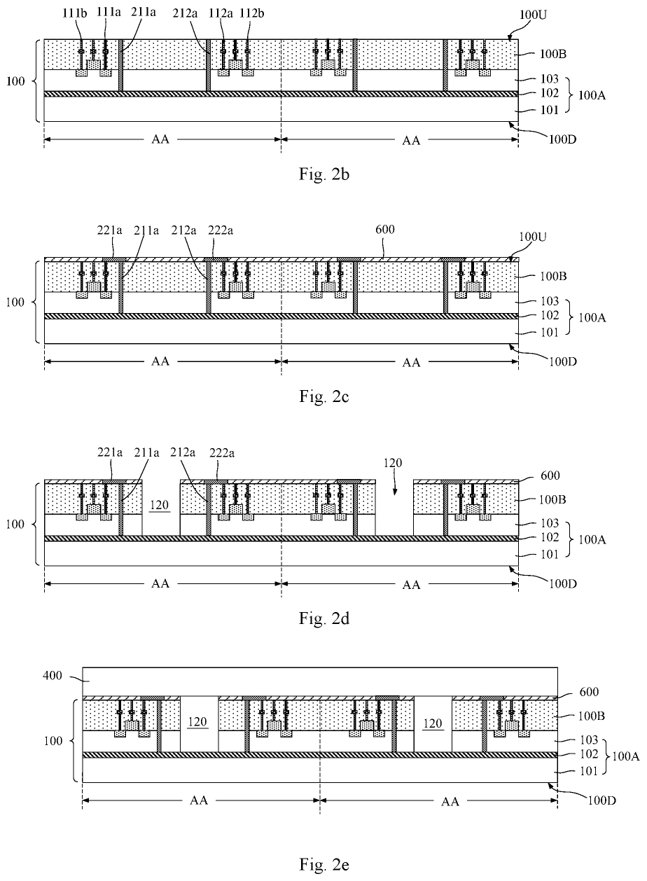

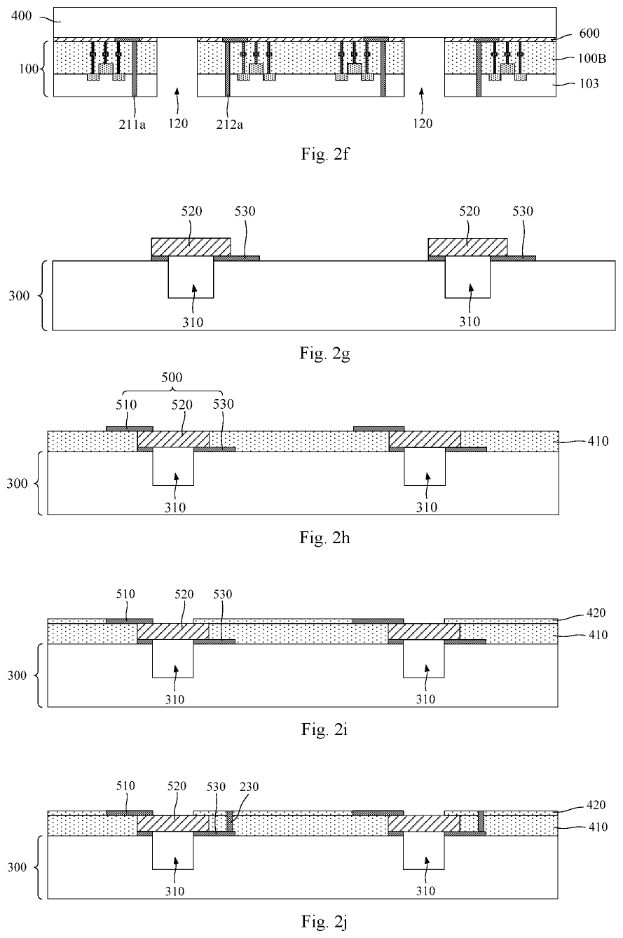

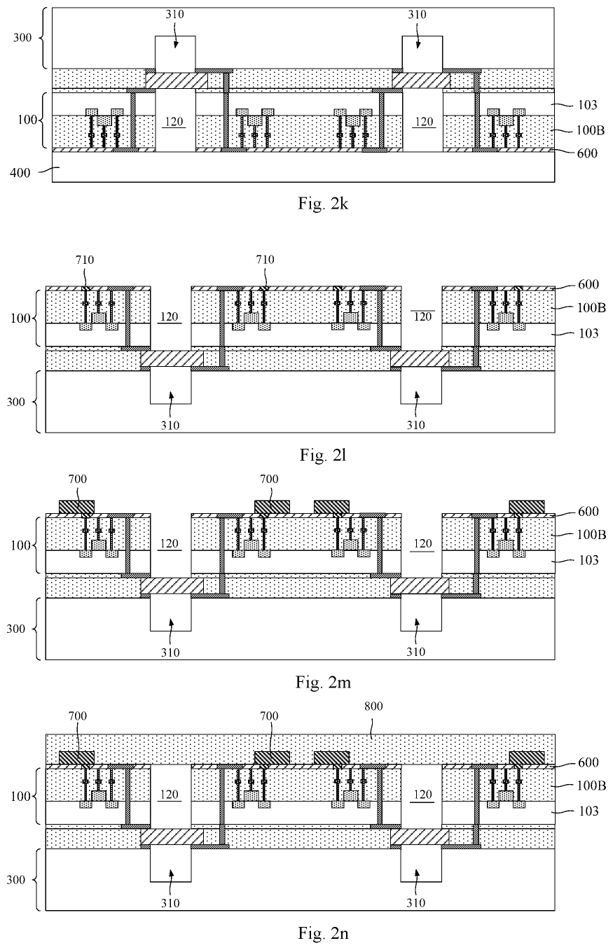

FIG. 1 shows a flowchart schematically illustrating a method for integrating a crystal resonator according to an embodiment of the present invention, and FIGS. 2a to 2l are schematic representations of structures resulting from steps in the method. In the following, steps for forming the crystal resonator will be described in detail with reference to the figures.

In step S100, with reference to FIG. 2a, a device wafer 100 is provided, in which a control circuit 110 is formed.

Specifically, the device wafer 100 may have a front side 100U and a back side 100D opposite to the front side, the control circuit 110 may include a plurality of interconnects, at least some of which extend to the front side of the device wafer. The control circuit 110 may be adapted to, for example, apply an electrical signal to the subsequently formed piezoelectric vibrator.

A plurality of crystal resonators may be formed on the same device wafer 100. Accordingly, there may be a plurality of device areas AA defined on the device wafer 100, with the control circuit 110 being formed in one of the device areas AA.

The control circuit 110 may include a first circuit 111 and a second circuit 112, the first circuit 111 and the second circuit 112 may be electrically connected to a top electrode and a bottom electrode for the subsequently formed piezoelectric vibrator, respectively.

With continued reference to FIG. 2a, the first circuit 111 may include a first transistor, a first interconnect 111a and a third interconnect 111b. The first transistor may be buried within the device wafer 100, and the first interconnect 111a and the third interconnect 111b may be both connected to the first transistor and extend to the front side of the device wafer 100. For example, the first interconnect 111a may be connected to a drain of the first transistor, and the third interconnect 111b may be connected to a source of the first transistor.

Similarly, the second circuit 112 may include a second transistor, a second interconnect 112a and a fourth interconnect 112b. The second transistor may be buried within the device wafer 100, and the second interconnect 112a and the fourth interconnect 112b may be both connected to the second transistor and extend to the front side of the device wafer 100. For example, the second interconnect 112a may be connected to a drain of the second transistor, and the fourth interconnect 112b may be connected to a source of the second transistor.

In this embodiment, the device wafer 100 may include a substrate wafer 100A and a dielectric layer 100B formed on the substrate wafer 100A. Additionally, the first and second transistors may be both formed on the substrate wafer 100A and covered by the dielectric layer 100B. The third interconnect 111b, the first interconnect 111a, the second interconnect 112a and the fourth interconnect 112b may be all formed within the dielectric layer 100B and extend to a surface of the dielectric layer 100B away from the substrate wafer.

The substrate wafer 100A may be either a silicon wafer or a silicon-on-insulator (SOI) wafer. In the case of the substrate wafer 100A being an SOI wafer, the substrate wafer may specifically include a base layer 101, a buried oxide layer 102 and a top silicon layer 103 stacked in sequence from the back side 100D to the front side 100U.

It is to be noted that, in this embodiment, the interconnects of the control circuit 110 extend to the front side 100U of the device wafer, while the subsequently formed piezoelectric vibrator is located on the back side 100D of the device wafer. Accordingly, a first connecting structure may be formed in a subsequent process for wiring signal ports of the control circuit 110 from the front side of the device wafer to back side of the device wafer and to the subsequently formed piezoelectric vibrator.

Specifically, the first connecting structure may include a first connection and a second connection. The first connection may be connected to the first interconnect 111a and adapted for electrical connection to the bottom electrode of the subsequently formed piezoelectric vibrator. The second connection may be connected to the second interconnect 112a and adapted for electrical connection to the top electrode of the subsequently formed piezoelectric vibrator.

In addition, with combined reference to FIGS. 2b and 2c, the first connection may include a first conductive plug 211a configured for electrical connection at its opposing ends respectively to the first interconnect 111a and the subsequently formed bottom electrode. That is, the first conductive plug 211a may function to wire a connecting port of the first interconnect 111a in the control circuit from a front side of the control circuit to a back side of the control circuit so as to enable electrical connection of the bottom electrode subsequently formed on the back side of the device wafer to the control circuit from the back side of the control circuit.

Optionally, in this embodiment, the first connection may further include a first connecting wire 221a, the first connecting wire 221a is formed, for example, on the front side of the device wafer. The first connecting wire 221a may be connected to one end of the first conductive plug 211a and the first interconnect, with the other end of the first conductive plug 211a being electrically connected to the bottom electrode.

Alternatively, in other embodiments, the first connecting wire in the first connection may be formed on the back side of the device wafer. In this case, the first connecting wire may be connected to one end of the first conductive plug 211a and the bottom electrode, with the other end of the first conductive plug 211a being electrically connected to the first interconnect in the control circuit.

Similarly, the second connection may include a second conductive plug 212a configured for electrical connection at its opposing ends respectively to the second interconnect 112a and the subsequently formed top electrode. That is, the second conductive plug 212a may function to wire a connecting port of the second interconnect 112a in the control circuit from the front to back side of the control circuit so as to enable electrical connection of the top electrode subsequently formed on the back side of the device wafer to the control circuit from the back side of the control circuit.

In this embodiment, the second connection may further include a second connecting wire 222a, the second connecting wire 222a is formed, for example, on the front side of the device wafer. The second connecting wire 222a may be connected to one end of the second conductive plug 212a and the second interconnect, with the other end of the second conductive plug 212a being electrically connected to the top electrode.

Alternatively, in other embodiments, the second connecting wire in the second connection may be formed on the back side of the device wafer. In this case, the second connecting wire may be connected to one end of the second conductive plug 212a and the top electrode, with the other end of the second conductive plug 212a being electrically connected to the second interconnect in the control circuit.

The first conductive plug 211a in the first connection and the second conductive plug 212a in the second connection may be formed in a single process step. The first connecting wire 221a in the first connection and the second connecting wire 222a in the second connection may also be formed in a single process step.

Specifically, in this embodiment, the formation of the first connection that includes the first conductive plug 211a and the first connecting wire 221a located on the front side of the device wafer and of the second connection that includes the second conductive plug 212a and the second connecting wire 222a located on the front side of the device wafer may include the following steps:

Step 1: Etch the device wafer 100 from the front side 100U of the device wafer so that a first connecting hole and a second connecting hole are formed. Specifically, both the first and second connecting holes may be located at the bottom closer to the back side 100D of the device wafer than the control circuit.

Step 2: With reference to FIG. 2b, fill a conductive material into the first and second connecting holes, thereby resulting in the formation of the first and second conductive plugs 211a, 212a.

In this embodiment, both the first and second conductive plugs 211a, 212a may be located at the bottom closer to the back side 100D of the device wafer than the control circuit. Specifically, the first and second transistors 111T, 112T may be formed within the top silicon layer 103 above the buried oxide layer 102, while the first and second conductive plugs 211a, 212a may penetrate sequentially through the dielectric layer 100B and the top silicon layer 103 and terminate at the buried oxide layer 102. Thus, it can be considered that the buried oxide layer 102 may serve as an etch stop layer for the etching process for forming the connecting holes. In this way, high etching accuracy can be achieved for the etching process.

Step 3: With reference to FIG. 2c, form, on the front side of the device wafer 100, the first connecting wire 221a and the second connecting wire 222, the first connecting wire 221a is connected to both the first conductive plug 211a and the first interconnect 111a and the second connecting wire 222a is connected to both the second conductive plug 212a and the second interconnect 112a.

The device wafer may be thinned from the back side in a subsequent process so that the first and second conductive plugs 211a, 212a are exposed at the back side of the device wafer 100 and brought into electrical connection with the piezoelectric vibrator formed on the back side thereof.

In embodiments with the first connecting wire in the first connection and the second connecting wire in the second connection being formed on the back side of the device wafer, the formation of the first connection that includes the first conductive plug and the first connecting wire and of the second connection that includes the second conductive plug and the second connecting wire may, for example, include:

first, forming a first connecting hole and a second connecting hole by etching the device wafer from the front side thereof the device wafer;

then forming the first conductive plug that is electrically connected to the first interconnect and the second conductive plug that is electrically connected to the second interconnect by filling a conductive material into the first and second connecting holes;

subsequently, thinning the device wafer from the back side thereof so that the first and second conductive plugs are exposed; and

forming, on the back side of the device wafer, the first connecting wire that is connected at one end to the first conductive plug and electrically connected at the other end to the bottom electrode and the second connecting wire that is connected at one end to the second conductive plug and electrically connected at the other end to the top electrode.

It is to be noted that although the first and second conductive plugs 211a, 212a have been described above as being formed from the front side of the device wafer prior to the formation of the first and second connecting wires 221a, 222a, the first and second conductive plugs 211a, 212a may alternatively formed from the back side of the device wafer subsequent to the thinning of the device wafer, as described in greater detail below.

In addition, in a subsequent process, a support wafer may be bonded to the front side 100U of the device wafer 100. Accordingly, subsequent to the formation of the first and second connecting wires 221a, 222a, the method may optionally include forming, on the front side 100U of the device wafer 100, a planarized layer 600 which provides the device wafer 100 with a more flat bonding surface.

With reference to FIG. 2c, the planarized layer 600 may be formed on the front side 100U of the device wafer 100 and may have a top surface that is not lower than those of the first and second connecting wires 221a, 222a. For example, the planarized layer 600 may cover the device wafer 100 and the first and second connecting wires 221a, 222a so as to provide a flatter top surface of the planarized layer 600. Alternatively, the top surface of the planarized layer 600 may also be flushed with those of the first and second connecting wires 221a, 222a so that it also provides the device wafer 100 with a flatter bonding surface.

In this embodiment, the planarized layer 600 may be formed by using a polishing process. In this case, for example, the first and second connecting wires 221a, 222a may serve as polish stops such that the top surface of the formed planarized layer 600 is flush with those of the first and second connecting wires 221a, 222a, and all these surfaces may make up the bonding surface for the device wafer 100.

In step S200, with reference to FIGS. 2d to 2f, a lower cavity 120 with an opening at the back side of the device wafer is formed in the device wafer 100.

In this embodiment, the lower cavity 120 may be formed, for example, using a method including the following steps S210 and S220.

In step S210, with reference to FIG. 2d, the lower cavity 120 of the crystal resonator is formed by etching the device wafer 100 from the front side of the device wafer 100.

Specifically, the lower cavity 120 extends deep into the device wafer 100 from the front side 100U of the device wafer 100 and the lower cavity 120 may be located at the bottom closer to the back side 100D of the device wafer than the control circuit 110.

In this embodiment, the lower cavity 120 may be formed by performing an etching process which proceeds sequentially through the planarized layer 600, the dielectric layer 100B and the top silicon layer 103 and stops at the buried oxide layer 102.

Thus, the buried oxide layer 102 may be used as an etch stop layer for both the etching process for forming the first and second connecting holes for the first and second conductive plugs 211a, 212a and the etching process for forming the lower cavity 120. As a result, bottoms of the resulting conductive plugs are at the same or similar level as that of the lower cavity 120. In this way, when the device wafer is subsequently thinned from the back side 100D of the device wafer 100, the first and second conductive plugs 211a, 212a and the lower cavity 120 can be both exposed.

It is to be noted that the relative positions of the lower cavity 120 and the first and second circuits shown in the appended drawings are merely for illustration, and in practice, the arrangement of the first and second circuits may depend on the actual circuit layout requirements. The present invention is not limited in this regard.

In step S220, with reference to FIGS. 2e and 2f, the device wafer 100 is thinned from the back side 100D of the device wafer 100 until the lower cavity 120 is exposed.

As discussed above, the lower cavity 120 may be bottomed at the buried oxide layer 102. Therefore, as a result of the thinning of the device wafer, the base layer 101 and the buried oxide layer 102 may be sequentially removed so that the top silicon layer 103 and the lower cavity 120 are exposed. Moreover, in this embodiment, since the first and second conductive plugs 211a, 212a may extend downward to the buried oxide layer 102, they may also be exposed as a result of the thinning of the device wafer. As such, it is made possible to electrically connect the exposed conductive plugs to the subsequently formed piezoelectric vibrator.

Optionally, with reference to FIG. 2e, before the device wafer 100 is thinned, a support wafer 400 may be bonded to the front side of the device wafer 100, so that the device wafer 100 is thinned under the support of the support wafer 400. At the same time, the support wafer 400 can close the opening of the lower cavity exposed at the front side of the device wafer.

It is to be noted that, in this embodiment, the lower cavity 120 is formed by etching the device wafer 100 from the front side and thinning the device wafer 100 from the back side so that the opening of the lower cavity 120 is exposed at the back side of the device wafer 100.

However, in other embodiments, referring to FIG. 4, the lower cavity 120 may be alternatively formed by etching the device wafer from the back side thereof. In still other embodiments, the etching process on the back side of the device wafer may be preceded by a thinning process of the device wafer.

With particular reference to FIG. 4, in one specific embodiment, the formation of the lower cavity by etching the device wafer from the back side thereof may include the following steps.

At first, the device wafer is thinned from the back side thereof. In case of the substrate wafer being an SOI wafer, this may involve sequential removal of the base layer and the buried oxide layer of the substrate wafer. Of course, the thinning of the substrate wafer may alternatively involve partial removal of the base layer, complete removal of the base layer and hence exposure of the buried oxide layer, or the like.

Next, the device wafer is etched from the back side so that the lower cavity is formed. It is to be noted that the lower cavity resulting from the etching of the device wafer may have a depth as practically required, and the present invention is not limited in this regard. For example, after the device wafer is thinned and the top silicon layer 103 is exposed, the top silicon layer 103 may be etched to form the lower cavity therein. Alternatively, the etching process may proceed through the top silicon layer 103 and further into the dielectric layer 100B, so that the resulting lower cavity 120 extends from the top silicon layer 103 into the dielectric layer 100B.

As discussed above, in other embodiments, the thinning of the device wafer may be followed by forming the first conductive plug 211a of the first connection and the second conductive plug 212a of the first connection from the back side of the device wafer 100.

Specifically, a method for forming the first and second connecting wires on the front side of the device wafer 100, forming the first and second conductive plugs 211a, 212a from the back side of the device wafer 100, connecting the first conductive plug 211a to the first connecting wire 221a and connecting the second conductive plug 212a to the second connecting wire 222a may include the steps detailed below.

At first, prior to the bonding of the support wafer 400, the first and second connecting wires 221a, 222a are formed on the front side of the device wafer 100.

The first connecting wire 221a may be electrical connected to the first interconnect 111a, and the second connecting wire 212a may be electrical connected to the second interconnect 112a.

Next, after the device wafer 100 is thinned, it is etched from the back side to form therein first and second connecting holes, both of which penetrate through the device wafer 100 so that the first and second connecting wires 221a, 222a are exposed, respectively.

Subsequently, a conductive material is filled in the first and second connecting holes, resulting in the formation of the first and second conductive plugs 211a, 212a.

The first conductive plug 211a may be connected at one end to the first connecting wire 221a, and the other end of the first conductive plug 211a may be configured for electrical connection to the bottom electrode of the piezoelectric vibrator. The second conductive plug 212a may be connected at one end to the second connecting wire 222a, and the other end of the second conductive plug 212a may be configured for electrical connection to the top electrode of the piezoelectric vibrator.

In an alternative embodiment, a method for forming the first and second connecting wires on the back side of the device wafer 100, forming the first and second conductive plugs from the back side of the device wafer 100, connecting the first conductive plug to the first connecting wire and connecting the second conductive plug to the second connecting wire may include the steps detailed below.

At first, the device wafer 100 is thinned from the back side thereof, followed by etching the device wafer 100 from the back side and thus forming first and second connecting holes therein.

Next, a conductive material is filled in the first and second connecting holes, resulting in the formation of the first and second conductive plugs. The first conductive plug may be electrically connected at one end to the first interconnect, and the second conductive plug may be electrically connected at one end to the second interconnect.

Subsequently, the first and second connecting wires are formed on the back side of the device wafer 100. One end of the first connecting wire may be connected to the other end of the first conductive plug, and the other end of the first connecting wire may be configured for electrical connection to the bottom electrode. One end of the second connecting wire may be connected to the other end of the second conductive plug, and the other end of the second connecting wire may be configured for electrical connection to the top electrode.

In step S300, with reference to FIG. 2g, a substrate 300 is provided and etched so that an upper cavity 310 of the crystal resonator is formed therein, the upper cavity 310 is formed in opposition to the lower cavity 120. Likewise, the upper cavity 310 may have a depth that is determined as practically required, and the present invention is not limited in this regard. In a subsequent process for bonding the substrate 300 to the device wafer 100, the upper and lower cavities 310, 120 may be positioned on opposing sides of the piezoelectric vibrator.

On the substrate 300, there may be also defined a plurality of device areas AA corresponding to those of the device wafer 100, and the lower cavity 120 may be formed in one of the device areas AA on the device wafer 100.

In step S400, a piezoelectric vibrator including a top electrode, a piezoelectric crystal and a bottom electrode is formed. Each of the top electrode, the piezoelectric crystal and the bottom electrode may be formed on one of the back side of the device wafer 100 and the substrate 300.

In other words, it is possible that the top electrode, the piezoelectric crystal and the bottom electrode in the piezoelectric vibrator are all formed on the back side of the device wafer 100, or on the substrate 300. It is also possible that the bottom electrode of the piezoelectric vibrator is formed on the back side of the device wafer 100, with the top electrode and piezoelectric crystal of the piezoelectric vibrator being formed as a stack on the substrate 300. It is still possible that the bottom electrode and the piezoelectric crystal of the piezoelectric vibrator are formed as a stack on the back side of the device wafer 100, with the top electrode of the piezoelectric vibrator being formed on the substrate 300.

In this embodiment, the top electrode, the piezoelectric crystal and the bottom electrode in the piezoelectric vibrator are all formed on the substrate 300. Specifically, a method for forming the piezoelectric vibrator on the substrate 300 may include the following steps:

Step 1: With reference to FIG. 2g, form the top electrode 530 at a predetermined position on a surface of the substrate 300. In this embodiment, the top electrode 530 is positioned around the upper cavity 310. In a subsequent process, the top electrode 530 is electrically connected to the control circuit 110 and, more exactly, to the second interconnect in the second circuit 112.

Step 2: With continued reference to FIG. 2g, bond the piezoelectric crystal 520 to the top electrode 530. In this embodiment, the piezoelectric crystal 520 is arranged above the upper cavity 310, with its peripheral edge portions residing on the top electrode 530. The piezoelectric crystal 520 may be, for example, a quartz crystal plate.

In this embodiment, the upper cavity 310 may be narrower than the piezoelectric crystal 520 so that the piezoelectric crystal 520 can be arranged with its peripheral edge portions residing on the surface of the substrate, thus covering an opening of the upper cavity 310.

However, in other embodiments, the upper cavity may, for example, be made up of a first portion and a second portion. The first portion may be deeper in the substrate than the second portion, while the second portion may be closer to the surface of the substrate. Additionally, the first portion may be narrower than the piezoelectric crystal 520, and the second portion may be wider than the piezoelectric crystal. In this case, the piezoelectric crystal 520 may be at least partially received in the second portion, with its peripheral edge portions residing on top edges of the first portion. In addition, it is devisable that the opening of the upper cavity is wider than the piezoelectric crystal.

Further, the top electrode 530 may have an extension laterally extending beyond the piezoelectric crystal 520 thereunder. In a subsequent process, the top electrode 530 is connected to the second interconnect in the second circuit 112 via the extension.

Step 3: With reference to FIG. 2h, form the bottom electrode 510 on the piezoelectric crystal 520. The bottom electrode 510 may be so formed that a central portion of the piezoelectric crystal 520 is exposed therefrom. In a subsequent process, the bottom electrode 510 is electrically connected to the control circuit 110 and, more exactly, to the first interconnect in the first circuit 111.

Thus, in the control circuit 110, the first circuit 111 is electrically connected to the bottom electrode 510, and the second circuit 112 to the top electrode 530. As such, an electrical signal can be applied to the bottom and top electrodes 510, 530 to create an electric field between the bottom electrode 510 and the top electrode 530, which causes the piezoelectric crystal 520 between the top and bottom electrodes 530, 510 to change its shape. The magnitude of the shape change of the piezoelectric crystal 520 depends on the strength of the electric field, and when the electric field between the top and bottom electrodes 530, 510 is inverted, the piezoelectric crystal 520 will change its shape in the opposite direction. Therefore, when the control circuit 110 applies an AC signal to the top and bottom electrodes 530, 510, the piezoelectric crystal 520 will change shape alternately in opposite directions and thus alternately contract and expand due to oscillations of the electric field. As a result, the piezoelectric crystal 520 will mechanically vibrate.

In this embodiment, a method for forming the bottom electrode 510 on the substrate 300 may include the steps detailed below.

In a first step, with reference to FIG. 2h, a first plastic encapsulation layer 410 is formed on the substrate 300, the first plastic encapsulation layer 410 covers the substrate 300, and from which the piezoelectric crystal 520 is exposed. It is to be noted that, in this embodiment, since the top electrode 530 is formed under the piezoelectric crystal 520, with the extension thereof extending laterally beyond the piezoelectric crystal 520, the first plastic encapsulation layer 410 also covers the extension of the top electrode 530.

In addition, a top surface of the first plastic encapsulation layer 410 may not be higher than that of the piezoelectric crystal 520. In this embodiment, the formation of the first plastic encapsulation layer 410 involves planarizing the first plastic encapsulation layer 410 so that its top surface is flush with that of the piezoelectric crystal 520.

In a second step, with continued reference to FIG. 2h, the bottom electrode 510 is formed on the surface of the piezoelectric crystal 520. The bottom electrode 510 has an extension extending laterally beyond the piezoelectric crystal 520 over the first plastic encapsulation layer 410. In a subsequent process, the bottom electrode 510 is connected to the control circuit (more exactly, to the first interconnect in the first circuit 111) via the extension.

The bottom and top electrodes 510, 530 each have a material including silver, and the bottom and top electrodes 510, 530 may be successively formed using a thin-film deposition process or a vapor deposition process.

It is to be noted that, in this embodiment, the top electrode 530, the piezoelectric crystal 520 and the bottom electrode 510 are successively formed over the substrate 300 using semiconductor processes. However, in other embodiments, it is also possible to form the top and bottom electrodes on opposing sides of the piezoelectric crystal and then bond the three as a whole onto the substrate.

Optionally, subsequent to the formation of the bottom electrode 510, the method may further include forming a second plastic encapsulation layer on the first plastic encapsulation layer 410, which provides the substrate 300 with a fatter surface favorable to the subsequent bonding process.

With reference to FIG. 2i, the second plastic encapsulation layer 420 is formed on the first plastic encapsulation layer 410, the second plastic encapsulation layer 420 may have a top surface not higher than that of the bottom electrode 510 so that the bottom electrode 510 remains exposed. In this embodiment, the formation of the second plastic encapsulation layer 420 may involve planarizing the second plastic encapsulation layer 420 so that its top surface is flush with that of the bottom electrode 510. Moreover, the central portion of the piezoelectric crystal 520 may also be exposed from the second plastic encapsulation layer 420. In this way, when the substrate 300 is subsequently bonded to the device wafer 100, the central portion of the piezoelectric crystal 520 can interface with the lower cavity 120 in the device wafer 100.

After that, a third conductive plug 230 of the second connection in the first connecting structure may be formed either on the device wafer 100 or on the substrate 300. As such, in a subsequent process, the bottom electrode 510 may be electrically connected to the control circuit in the device wafer 100 via the first conductive plug and the first connecting wire of the first connection, and the top electrode 530 on the substrate 300 may be electrically connected to the control circuit in the device wafer 100 via the second conductive plug, second connecting wire and third conductive plug 230 of the second connection.

Specifically, with combined reference to FIGS. 2j and 2f, in this embodiment, the bottom electrode 510 is exposed at the surface of the second plastic encapsulation layer 420 and has the extension, and the first conductive plug 211a is exposed at the top from the surface of the device wafer 100. As such, the device wafer 100 can be bonded to the substrate 300 such that the bottom electrode 510 resides on the surface of the device wafer 100, with the extension of the bottom electrode being connected to the first conductive plug 211a.

With continued reference to FIGS. 2j and 2f, the top electrode 530 is buried in the first plastic encapsulation layer 410, and the extension of the top electrode 530 is electrically connected to the second conductive plug 212a via the third conductive plug.

In this embodiment, the top electrode 530 and the piezoelectric crystal 520 are successively formed on the substrate 300, followed by the formation of the third conductive plug of the second connection on the substrate 300. Specifically, the third conductive plug 230 of the second connection may be formed using a method including the steps detailed below.

At first, a plastic encapsulation layer is formed on the surface of the substrate 300. In this embodiment, the plastic encapsulation layer is made up of the aforementioned first plastic encapsulation layer 410 and second plastic encapsulation layer 420.

Next, with reference to FIG. 2j, a through hole is formed in the plastic encapsulation layer, in which the top electrode 530 is exposed, and a conductive material is then filled in the through hole, resulting in the formation of the third conductive plug 230 that is electrically connected at one end to the top electrode 530. More exactly, the third conductive plug 230 is connected to the extension of the top electrode 530.

In this embodiment, the through hole is formed by successively etching through the second plastic encapsulation layer 420 and the first plastic encapsulation layer 410, and a conductive material is then filled in the through hole, resulting in the formation of the third conductive plug 230. The third conductive plug 230 is electrically connected at one end to the top electrode 530 and exposed at the other end at the surface of the second plastic encapsulation layer 420. As such, the device wafer 100 can be bonded to the substrate 300 so that the other end of the third conductive plug 230 is electrically connected to the second conductive plug 212a.

In step S500, with reference to FIG. 2k, the substrate 300 is bonded to the back side of the device wafer 100 such that the piezoelectric vibrator 500 is situated between the device wafer 100 and the substrate 300, with the upper and lower cavities 310, 120 being located on opposing sides of the piezoelectric vibrator 500 to form the crystal resonator. In addition, the top and bottom electrodes 530, 510 of the piezoelectric vibrator 500 are both electrically connected to the control circuit through the first connecting structure.

As discussed above, in this embodiment, the device wafer 100 and the substrate 300 are so bonded that, in the control circuit, the first circuit 111 is electrically connected to the bottom electrode 510 by the first connection (including the first conductive plug and the first connecting wire) and the second circuit 112 is electrically connected the top electrode 530 by the second connection (including the second conductive plug, the second connecting wire and the third conductive plug). In this way, the control circuit can apply an electrical signal to the electrodes sandwiching the piezoelectric crystal 520, which causes the piezoelectric crystal 520 to change its shape and vibrate in the upper and lower cavities 310, 120.

The bonding of the device wafer 100 and the substrate 300 may be accomplished by a method, for example, including: applying adhesive layer(s) to the device wafer 100 and/or the substrate 300; and bonding the device wafer 100 and the substrate 300 together by means of the adhesive layer(s). Specifically, an adhesive layer may be applied to the substrate with the piezoelectric crystal formed thereon in such a manner that the surface of the piezoelectric crystal is exposed at a surface of the adhesive layer, and the substrate without the piezoelectric crystal formed thereon may be then bonded to the adhesive layer.

In this embodiment, the piezoelectric vibrator 500 is formed on the substrate 300. Accordingly, the bonding of the device wafer 100 and the substrate 300 may be accomplished by a method, for example, including: applying an adhesive layer to the substrate 300 so that the surface of the piezoelectric vibrator 500 is exposed at a surface of the adhesive layer; and then bonding together the substrate 300 and the device wafer 100 by means of the adhesive layer.

Therefore, in this embodiment, the top electrode 530, the piezoelectric crystal 520 and the bottom electrode 510 of the piezoelectric vibrator 500 are all formed on the substrate 300, and the piezoelectric vibrator 500 covers the opening of the upper cavity 310. In addition, the bonding is so performed that the lower cavity 120 is located on the side of the piezoelectric vibrator 500 away from the upper cavity 310 and the crystal resonator is thus formed. In addition, the crystal resonator is electrically connected to the control circuit in the device wafer 100, achieving the integration of the crystal resonator with the control circuit.

In step S600, with reference to FIGS. 2l to 2m, a semiconductor die 700 is bonded to the front side of the device wafer in such a manner that the semiconductor die 700 is electrically connected to the control circuit by a second connecting structure.

In the semiconductor die 700, for example, a drive circuit for providing an electrical signal may be formed. The electrical signal is applied by the control circuit to the piezoelectric vibrator 500 so as to control shape change of the piezoelectric vibrator 500.

The semiconductor die 700 may be heterogeneous from the device wafer 100. That is, the semiconductor die 700 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (e.g., germanium, germanium silicon, silicon germanium, etc.)

In this embodiment, the bonding of the semiconductor die to the front side of the device wafer 100 is preceded by removal of the support wafer, and the semiconductor die is electrically connected to the control circuit by the second connecting structure.

With reference to FIGS. 2l to 2m, the formation of the second connecting structure may involve forming a contact pad on the front side of the device wafer, which is electrically connected at the bottom to the control circuit and at the top to the semiconductor die.

In this embodiment, the formation of the contact pad in the second connecting structure may include forming a contact hole by etching in the planarized layer 300 and then filling a conductive material in the contact hole, as shown in FIG. 2l. The resulting contact pad 710 is connected to the control circuit. In this way, the semiconductor die 700 can be so bonded to the front side of the device wafer that the semiconductor die 700 is electrically connected to the contact pad 710.

In other embodiments, a rewiring layer, which is connected to the control circuit, may be further formed on the front side of the device wafer. In this case, the contact pad for electrical connection to the semiconductor die may be formed on the rewiring layer.

Optionally, with reference to FIG. 2n, a cap substrate 800 may be further bonded to the front side of the device wafer 100 so as to cover the semiconductor die 700 and the opening of the lower cavity exposed at the front side of the device wafer.

The cap substrate 800 may be, for example, a silicon substrate. In the cap substrate 800, a depression for receiving the semiconductor die 700 may be formed in advance. Accordingly, the cap substrate 800 may be bonded to the front side of the device wafer so that the opening of the lower cavity at the front side of the device wafer is covered and closed, with the semiconductor die 700 being received in the depression formed in the cap substrate 800.

It is to be noted that, although it has been described above in this embodiment that the bonding of the substrate to the back side of the device wafer is followed by the bonding of the semiconductor die to the front side of the device wafer, in other embodiments, it is also possible that the semiconductor die is bonded to the front side of the device wafer before the substrate is bonded to the back side of the device wafer.

### Embodiment 2

Differing from Embodiment 1, in this embodiment, the top electrode 530, the piezoelectric crystal 520 and the bottom electrode 510 of the piezoelectric vibrator 500 are all formed on the back side of the device wafer 100, and the piezoelectric vibrator 500 covers and closes the opening of the lower cavity 120. In addition, after the crystal resonator is electrically connected to the control circuit in the device wafer 100, a bonding process is performed so that the upper cavity 310 is located on the side of the piezoelectric vibrator 500 away from the lower cavity 120. Forming the crystal resonator in this way allows integration of the crystal resonator with the control circuit.

Reference can be made to the description of Embodiment 1 for details in the provision of the device wafer containing the control circuit and the formation of the lower cavity in the device wafer, and these are not described here again for the sake of brevity.

According to this embodiment, the formation of the piezoelectric vibrator 500 on the device wafer 100 may include the steps detailed below.

At first, the bottom electrode 510 is formed at a predetermined position on the back side of the device wafer 100. In this embodiment, the bottom electrode 510 is positioned around the lower cavity 120.

Then, the piezoelectric crystal 520 is bonded to the bottom electrode 510. In this embodiment, the piezoelectric crystal 520 is so bonded above the lower cavity 120 that it covers and closes the opening of the lower cavity 120, with the peripheral edge portions of the piezoelectric crystal 520 residing on the bottom electrode 510.

Next, the top electrode 530 is formed on the piezoelectric crystal 520.

Of course, in other embodiments, it is also possible to form the top and bottom electrodes respectively on the opposing sides of the piezoelectric crystal and then bond the three as a whole to the back side of the device wafer 100.

Thereafter, the first connecting structure including the first connection for electrical connection to the bottom electrode and the second connection for electrical connection to the top electrode is formed on the device wafer 100. The first connection includes the first conductive plug and first connecting wire, and the second connection includes the second conductive plug and second connecting wire. Reference can be made to the description of Embodiment 1 for details in the formation of the first conductive plug, the first connecting wire, the second conductive plug and the second connecting wire, and these are not described here again for the sake of brevity.

In addition, the second connection includes the third conductive plug 230, the third conductive plug 230 may be formed subsequent to the formation of the piezoelectric crystal 520 and prior to the formation of the top electrode 530. A method for forming the third conductive plug prior to the formation of the top electrode may include the following steps:

Step 1: Form a plastic encapsulation layer on the back side of the device wafer 100. In this embodiment, the plastic encapsulation layer covers the back side of the device wafer 100, with the piezoelectric crystal 520 being exposed therefrom.

Step 2: Form a through hole in the plastic encapsulation layer and fill a conductive material in the through hole, thereby resulting in the formation of the third conductive plug 230. The resulting third conductive plug 230 is electrically connected to the second conductive plug at the bottom and exposed from the plastic encapsulation layer at the top.

Step 3: Form the top electrode 530 on the device wafer 100 in such a manner that the top electrode 530 covers at least part of the piezoelectric crystal 520 and extends therefrom over the top of the third conductive plug and thus comes into electrical connection with the conductive plug. That is, the extension of the top electrode 530 extending beyond the piezoelectric crystal is directly electrically connected to the third conductive plug 230.

Alternatively, in step 3, after the top electrode 530 is formed on the piezoelectric crystal 520, an interconnecting wire may be formed on the top electrode 530 so as to extend beyond the top electrode over the top of the third conductive plug. In this way, the top electrode is electrically connected to the third conductive plug via the interconnecting wire. That is, the electrical connection between the top electrode 530 and the third conductive plug is accomplished by the interconnecting wire.

In addition, the bonding of the device wafer 100 and the substrate 300 may include: applying an adhesive layer to the device wafer 100 in such a manner that the surface of the piezoelectric crystal is exposed from the adhesive layer; and then bonding the device wafer 100 and the substrate 300 together by means of the adhesive layer.

The bonding may be so carried out that the upper cavity in the substrate 300 is located on the side of the piezoelectric crystal 520 away from the lower cavity. The upper cavity may be broader than the piezoelectric crystal so that the piezoelectric crystal can be accommodated within the upper cavity.

Reference can be made to the description of Embodiment 1 for details in bonding the semiconductor die to the front side of the device wafer and in electrically connecting the semiconductor die to the control circuit via the second connecting structure, and these are not described here again for the sake of brevity.

### Embodiment 3

Differing from Embodiments 1 and 2 in which the top electrode, piezoelectric crystal and bottom electrode of the piezoelectric vibrator are all formed either on the substrate or on the device wafer, in this embodiment, the top electrode and piezoelectric crystal are formed on the substrate, while the bottom electrode is formed on the device wafer.

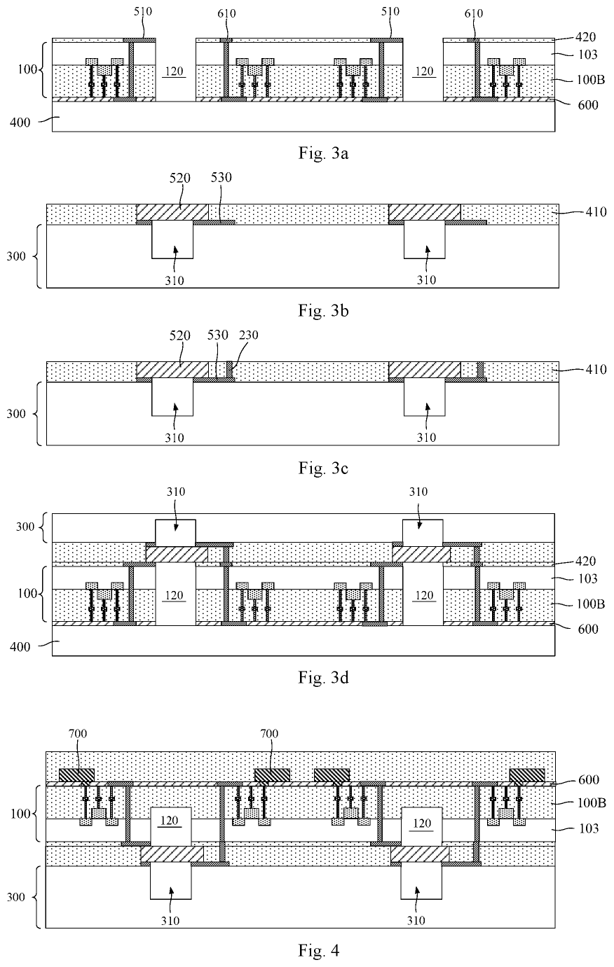

FIGS. 3a to 3d are schematic representations of structures resulting from steps in a method for integrating a crystal resonator with a control circuit according to the third embodiment of the present invention. In the following, steps for forming the crystal resonator will be described in detail with reference to the figures.

Referring now to FIG. 3a, the device wafer 100 containing the control circuit is provided, and the bottom electrode 510 is formed on the back side of the device wafer 100 so that the bottom electrode 510 is electrically connected to the first conductive plug in the first connecting structure.

During the formation of the bottom electrode 510, a rewiring layer 610 may be formed on the device wafer 100, which covers the second conductive plug in the first connecting structure.

In addition, subsequent to the formation of the bottom electrode 510, the method may further include forming a second plastic encapsulation layer 420 on the device wafer 100, which has a surface that is not higher than that of the bottom electrode 510 so that the bottom electrode 510 remains exposed. In this embodiment, the surface of the second plastic encapsulation layer 420 is also higher than that of the rewiring layer 610 so that the rewiring layer 610 is also exposed. In this way, a subsequent bonding process may be so performed that the bottom electrode 510 is positioned on one side of the piezoelectric crystal, with the rewiring layer 610 being electrically connected to the top electrode located on the other side of the piezoelectric crystal.

The formation of the second plastic encapsulation layer 420 may involve a planarization process for making the surface of the second plastic encapsulation layer 420 flush with that of the bottom electrode 510. In this way, a significant improved surface flatness can be provided to the device wafer 100, which is favorable to the subsequent bonding process.

With continued reference to FIG. 3a, in this embodiment, subsequent to the successive formation of the bottom electrode 510 and the second plastic encapsulation layer 420, the lower cavity 120 can be formed by successively etching through the second plastic encapsulation layer 420 and the dielectric layer 100B so that the bottom electrode 510 is positioned around the lower cavity 120.

After that, referring to FIG. 3b, the substrate 300 is provided and the top electrode 530 and the piezoelectric crystal 520 are successively formed thereon above the upper cavity. The top electrode may be formed using a vapor deposition process or a thin-film deposition process, followed by bonding the piezoelectric crystal to the top electrode.

Specifically, the top electrode 530 is positioned around the upper cavity 310 and will be electrically connected to the rewiring layer 610 on the device wafer 100 and hence the second interconnect 112a in the second circuit 112 in a subsequent process. Moreover, the piezoelectric crystal 520 may be so positioned that a central portion thereof interfaces with the upper cavity 310 in the substrate 300, with the peripheral edge portions of the piezoelectric crystal 520 residing on top edges of the top electrode 530. Moreover, an extension of the top electrode 530 may extend beyond the piezoelectric crystal 520 thereunder.

With continued reference to FIG. 3b, in this embodiment, subsequent to the formation of the piezoelectric crystal 520, the method may further include forming a first plastic encapsulation layer 410 on the substrate 300, which covers the substrate 300 and the extension of the top electrode 530. The first plastic encapsulation layer 410 may have a surface not higher than that of the piezoelectric crystal 520 so that the piezoelectric crystal 520 is exposed therefrom.

Similarly, in this embodiment, the formation of the first plastic encapsulation layer 410 may also involve a planarization process for making the surface of the first plastic encapsulation layer 410 flush with that of the piezoelectric crystal 520. In this way, the substrate 300 may be provided with a flatter surface, which is favorable to the subsequent bonding process.

Subsequently, referring to FIG. 3c, the third conductive plug 230 of the first connecting structure for electrically connecting the top electrode 530 to the second conductive plug is formed in the device wafer or the substrate. The formation of the third conductive plug 230 may include the steps detailed below.

At first, a plastic encapsulation layer is formed on the surface of the substrate 100. In this embodiment, the plastic encapsulation layer is made up of the aforementioned first plastic encapsulation layer 410.

Next, the plastic encapsulation layer is etched so that a through hole is formed therein. In this embodiment, the first plastic encapsulation layer 410 is etched, and the extension of the top electrode 530 is exposed in the resulting through hole. A conductive material is then filled in the through hole, resulting in the formation of the third conductive plug 230, which is exposed at the top at the surface of the first plastic encapsulation layer 410. Specifically, the third conductive plug 230 is connected to the extension of the top electrode 530. As a result, the top electrode 530 is electrically connected to the second conductive plug via the third conductive plug 230 and the rewiring layer 610.

Afterward, referring to FIG. 3d, the substrate 300 is bonded to the back side of the device wafer so that the lower cavity 120 is positioned on the side of the piezoelectric crystal 520 away from the upper cavity 310. Accordingly, the bottom electrode 510 on the device wafer 100 is located on the side of the piezoelectric crystal 520 away from the top electrode 530.

In this embodiment, the bonding of the substrate 300 to the device wafer 100 may include: applying an adhesive layer to the substrate 300 in such a manner that the surface of the piezoelectric crystal 520 is exposed from the adhesive layer; and then bonding the device wafer and the substrate together by means of the adhesive layer.

Specifically, the bonding of the substrate 300 to the device wafer 100 may bring the rewiring layer 610 on the device wafer 100 that is connected to the second conductive plug into electrical contact with the third conductive plug 230 on the substrate 300 that is connected to the top electrode 530, resulting in electrical connection of the top electrode 530 to the control circuit.

In a subsequent process, the semiconductor die is bonded to the front side of the device wafer so as to be electrically connected to the control circuit. Reference can be made to the description of Embodiment 1 for more details in this regard, and a repeated description thereof will be omitted here for the sake of brevity.

A structure for integrating a crystal resonator with a control circuit corresponding to the above method will be described below with combined reference to FIGS. 2a to 2n and 3d. The crystal resonator includes:

a device wafer 100, in which the control circuit and a lower cavity 120 are formed, the lower cavity 120 having an opening at a back side of the device wafer, the control circuit including interconnects, at least some of which extend to a front side of the device wafer 100;

a substrate 300, which is bonded to the device wafer 100 from the back side thereof, and an upper cavity 310 is formed in the substrate 300, the upper cavity 310 having an opening facing the device wafer 100, i.e., in opposition to the opening of the lower cavity 120;

a piezoelectric vibrator 500 including a bottom electrode 510, a piezoelectric crystal 520 and a top electrode 530, the piezoelectric vibrator 500 arranged between the device wafer 100 and the substrate 300 so that the lower and upper cavities 120, 310 are on opposing sides of the piezoelectric vibrator 500;

a first connecting structure configured to electrically connect the top and bottom electrodes 530, 510 of the piezoelectric vibrator 500 to the control circuit;

a semiconductor die 700 bonded to a front side of the device wafer 100, wherein in the semiconductor die 700, there is formed, for example, a drive circuit for producing an electrical signal to be transmitted to the piezoelectric vibrator 500 via the control circuit 100; and

a second connecting structure configured to electrically connect the semiconductor die 700 to the control circuit.

The semiconductor die 700 may be heterogeneous from the device wafer 100. That is, the semiconductor die 700 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (e.g., germanium, germanium silicon, silicon germanium, etc.)

The lower cavity 120 in the device wafer 100 and the upper cavity 310 in the substrate 300 may be formed using planar fabrication processes, and the device wafer 100 and the substrate 300 may be bonded together so that the upper and lower cavities 120, 310 are positioned in opposition to each other and respectively on opposing sides of the piezoelectric vibrator 500. In this way, the piezoelectric vibrator 500 and the control circuit can be integrated on the same device wafer so that the control circuit can cause the piezoelectric vibrator 500 to oscillate within the upper and lower cavities 310, 120. In addition, the semiconductor die bonded to the device wafer 100 can enhance performance of the crystal resonator by on-chip modulation under the control of the control circuit 110 for correcting raw deviations of the crystal resonator such as temperature and frequency drifts. Therefore, in addition to an enhanced degree of integration, the crystal resonator of the present invention fabricated using the semiconductor processes are more compact in size and thus less power-consuming.

With continued reference to FIG. 2a, the control circuit may include a first circuit 111 and a second circuit 112, the first circuit 111 and the second circuit 112 are electrically connected the top and bottom electrodes of the piezoelectric vibrator 500, respectively.

Specifically, the first circuit 111 may include a first transistor, a first interconnect 111a and a third interconnect 111b. The first transistor may be buried within the device wafer 100, and the first interconnect 111a and the third interconnect 111b may be both connected to the first transistor and extend to the front side of the device wafer 100. The first interconnect 111a may be electrically connected to the bottom electrode 510 and the third interconnect 111b to the semiconductor die.

Similarly, the second circuit 112 may include a second transistor, a second interconnect 112a and a fourth interconnect 112b. The second transistor may be buried within the device wafer 100, and the second interconnect 112a and the fourth interconnect 112b may be both connected to the second transistor and extend to the front side of the device wafer 100. The second interconnect 112a may be electrically connected to the top electrode 530 and the fourth interconnect 112b to the semiconductor die.

In addition, the first connecting structure may include a first connection and a second connection. The first connection may be connected to the first interconnect 111a and the bottom electrode 510 of the piezoelectric vibrator. The second connection may be connected to the second interconnect 112a and the top electrode 530 of the piezoelectric vibrator.

The first connection may include a first conductive plug 211a, which penetrates through the device wafer 100 so as to extend to the front side of the device wafer 100 into electrical connection with the first interconnect at one end and to extend to the back side of the device wafer 100 into electrical connection with the bottom electrode 510 of the piezoelectric vibrator 500 at the other end.

The first connection may further include a first connecting wire 211. In this embodiment, the first connecting wire 221a is formed on the front side of the device wafer 100 and connected to both the first conductive plug 211a and the first interconnect 111a. In alternative embodiments, the first connecting wire 221a may be formed on the back side of the device wafer 100 and connected to both the first conductive plug and the bottom electrode.

In this embodiment, the bottom electrode 510 is situated on the back side of the device wafer 100 around the lower cavity 120 and has an extension extending laterally beyond the piezoelectric crystal 520. Additionally, the extension of the bottom electrode covers the first conductive plug 211a so as to bring the bottom electrode 210 into electrical connection of the first interconnect 111a in the first circuit 111.

The second connection may include a second conductive plug 212a, which penetrates through the device wafer 100 so as to extend to the front side of the device wafer 100 into electrical connection with the second interconnect at one end and to extend to the back side of the device wafer 100 into electrical connection with the top electrode 530 of the piezoelectric vibrator 500 at the other end.

The second connection may further include a second connecting wire 222a. In this embodiment, the second connecting wire 222a is formed on the front side of the device wafer 100 and connected to both the second conductive plug 212a and the second interconnect 112a. In alternative embodiments, the second connecting wire 222a may be formed on the back side of the device wafer 100 and connected to both the second conductive plug and the top electrode.

The second connection may further include a third conductive plug, which is electrically connected to the top electrode 530 at one end and to the second conductive plug 212a at the other end. For example, the top electrode may extend beyond the piezoelectric crystal over the top of the third conductive plug.

Specifically, a plastic encapsulation layer may be arranged between the device wafer 100 and the substrate 300 such as to cover side surfaces of the piezoelectric crystal 220 and both the extensions of the top and bottom electrodes. The third conductive plug 230 of the second connection may penetrate through the plastic encapsulation layer so as to be connected to the extension of the top electrode at one end and to the second conductive plug at the other end.

Of course, in other embodiments, the second connection may further include an interconnecting wire, which covers the top electrode 530 at one end and covers at least part of the top of the third conductive plug at the other end. In this way, the interconnecting wire is connected to the third conductive plug.

In addition, the second connecting structure may include a contact pad 710, which is electrically connected to the control circuit at the bottom and to the semiconductor die 700 at the top.

With continued reference to FIG. 2a, in this embodiment, the device wafer 100 includes a substrate wafer 100A and a dielectric layer 100B. The first and second transistors may be both formed on the substrate wafer 100A, and the dielectric layer 100B may reside on the substrate wafer 100A and thus cover both the first and second transistors. Each of the third interconnect 111b, the first interconnect 111a, the fourth interconnect 112b and the second interconnect 112a may be formed in the dielectric layer 100B such as to extend to the surface of the dielectric layer 100B away from the substrate wafer 100A.

In this embodiment, the lower cavity may extend through the device wafer and thus further have an opening at the front side of the device wafer. In this case, the crystal resonator may further include a cap substrate, which is bonded to the front side of the device wafer and thus covers the semiconductor die 700. The cap substrate may be, for example, a silicon substrate. In the cap substrate, a depression for receiving the semiconductor die 700 may be formed in advance. Accordingly, the cap substrate may be bonded to the front side of the device wafer in such a manner that the opening of the lower cavity at the front side of the device wafer is covered and closed, with the semiconductor die 700 being received in the depression formed in the cap substrate.

In summary, in the method of the present invention, integration of the crystal resonator with the control circuit on the same device wafer is accomplished by bonding the substrate containing the upper cavity to the device wafer containing the lower cavity so that the piezoelectric vibrator is sandwiched between the device wafer and the substrate, with the lower and upper cavities being positioned on the opposing sides of the piezoelectric vibrator. Additionally, for example, the semiconductor die containing the drive circuit may be further bonded to the front side of the device wafer. In other words, the semiconductor die, control circuit and crystal resonator may be integrated on the same semiconductor substrate. This is favorable to on-chip modulation for correcting raw deviations of the crystal resonator such as temperature and frequency drifts. Compared with traditional crystal resonators (e.g., surface-mount ones), in addition to being able to integrate with other semiconductor components more easily with a higher degree of integration, the crystal resonator of the present invention that is fabricated using planar fabrication processes is more compact in size and hence less power-consuming.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer having the control circuit formed therein;
forming, in the device wafer, a lower cavity with an opening at a back side of the device wafer;
providing a substrate and etching the substrate so that an upper cavity of the crystal resonator is formed therein, wherein the upper cavity is formed in opposition to the lower cavity;
forming a piezoelectric vibrator comprising a top electrode, a piezoelectric crystal and a bottom electrode, which are formed on either of the back side of the device wafer and the substrate;
forming a first connecting structure on the device wafer or on the substrate;
bonding the substrate to the back side of the device wafer such that the piezoelectric vibrator is located between the device wafer and the substrate, with the upper cavity and the lower cavity being located on two sides of the piezoelectric vibrator, and with the first connecting structure electrically connecting both the top and bottom electrodes of the piezoelectric vibrator to the control circuit; and
bonding a semiconductor die to a front side of the device wafer and forming a second connecting structure, wherein the semiconductor die is electrically connected to the control circuit via the second connecting structure.

2. The method for integrating a crystal resonator with a control circuit of claim 1, wherein the device wafer comprises a substrate wafer and a dielectric layer on the substrate wafer, and wherein the substrate wafer is a silicon-on-insulator substrate comprising a base layer, a buried oxide layer and a top silicon layer stacked in sequence from the back side to the front side.

3. (canceled)

4. The method for integrating a crystal resonator with a control circuit of claim 1, wherein the formation of the lower cavity comprises: etching the device wafer from the front side thereof, thereby resulting in the formation of the lower cavity of the crystal resonator; thinning the device wafer from the back side thereof, thereby exposing the lower cavity; and bonding a cap substrate to the front side of the device wafer so that the cap substrate covers the opening of the lower cavity at the front side of the device wafer, or
wherein the formation of the lower cavity comprises etching the device wafer from the back side thereof, thereby resulting in the formation of the lower cavity of the crystal resonator, and
wherein the device wafer comprises a silicon-on-insulator substrate including a base layer, a buried oxide layer and a top silicon layer stacked in sequence from the back side to the front side, and
wherein the method further comprises, prior to forming the lower cavity by etching the device wafer from the back side thereof, removing the base layer and the buried oxide layer, and forming the lower cavity by etching the device wafer from the back side thereof comprises forming the lower cavity by etching the top silicon layer.

5. (canceled)

6. The method for integrating a crystal resonator with a control circuit of claim 1, wherein the piezoelectric vibrator is formed on the back side of the device wafer or on the substrate, or wherein the bottom electrode of the piezoelectric vibrator is formed on the back side of the device wafer, and the top electrode and the piezoelectric crystal of the piezoelectric vibrator are sequentially formed on the substrate, or wherein the bottom electrode and the piezoelectric crystal of the piezoelectric vibrator are sequentially formed on the back side of the device wafer and the top electrode of the piezoelectric vibrator is formed on the substrate, and
wherein the top electrode is formed on the substrate and the bottom electrode is formed on the back side of the device wafer, wherein each of the top and bottom electrodes is formed using a vapor deposition process or a thin-film deposition process, and wherein the piezoelectric crystal is bonded to the top electrode or the bottom electrode.

7. The method for integrating a crystal resonator with a control circuit of claim 6, wherein the formation of the piezoelectric vibrator on the back side of the device wafer comprises:
forming the bottom electrode at a predetermined position on the back side of the device wafer;
bonding the piezoelectric crystal to the bottom electrode; and
forming the top electrode on the piezoelectric crystal, or comprises:
forming the top and bottom electrodes of the piezoelectric vibrator on the piezoelectric crystal; and bonding the top and bottom electrodes and the piezoelectric crystal as a whole to the back side of the device wafer, or wherein
the formation of the piezoelectric vibrator on the substrate comprises:
forming the top electrode at a predetermined position on a surface of the substrate;
bonding the piezoelectric crystal to the top electrode; and
forming the bottom electrode on the piezoelectric crystal, or comprises:
forming the top and bottom electrodes of the piezoelectric vibrator on the piezoelectric crystal; and bonding the top and bottom electrodes and the piezoelectric crystal as a whole to the substrate,
wherein the formation of the bottom electrode comprises a vapor deposition process or a thin-film deposition process, and wherein the formation of the top electrode comprises a vapor deposition process or a thin-film deposition process.

8-10. (canceled)

11. The method for integrating a crystal resonator with a control circuit of claim 1, wherein the control circuit comprises a first interconnect and a second interconnect and the first connecting structure comprises a first connection and a second connection,
the first connection connected to both the first interconnect and the bottom electrode of the piezoelectric vibrator, the second connection connected to both the second interconnect and the top electrode of the piezoelectric vibrator.

12. The method for integrating a crystal resonator with a control circuit of claim 11, wherein the first connection is formed prior to the formation of the bottom electrode, and wherein:
the first connection comprises a first conductive plug in the device wafer, two ends of the first conductive plug configured to be electrically connected respectively to the first interconnect and the bottom electrode; or
the first connection comprises a first conductive plug in the device wafer and a first connecting wire on the back side of the device wafer, the first connecting wire electrically connected to one end of the first conductive plug, the first conductive plug electrically connected at the other end to the first interconnect, the first connecting wire electrically connected to the bottom electrode; or
the first connection comprises a first conductive plug in the device wafer and a first connecting wire on the front side of the device wafer, the first connecting wire electrically connected to one end of the first conductive plug, the first conductive plug electrically connected at the other end to the bottom electrode, the first connecting wire electrically connected to the first interconnect.

13. The method for integrating a crystal resonator with a control circuit of claim 12, wherein the formation of the first connection comprising the first conductive plug and the first connecting wire on the front side of the device wafer comprises:
forming a first connecting hole by etching the device wafer from the front side thereof;
filling a conductive material in the first connecting hole, thus resulting in the formation of the first conductive plug;
forming the first connecting wire on the front side of the device wafer, the first connecting wire connected to the first conductive plug and the first interconnect;
thinning the device wafer from the back side thereof so that the first conductive plug is exposed and becomes available for electrical connection to the bottom electrode of the piezoelectric vibrator, or wherein
the formation of the first connection comprising the first conductive plug and the first connecting wire on the front side of the device wafer comprises:
forming the first connecting wire on the front side of the device wafer, the first connecting wire electrically connected to the first interconnect;
thinning the device wafer from the back side thereof and forming a first connecting hole by etching the device wafer from the back side thereof, the first connecting hole penetrating through the device wafer so that the first connecting wire is exposed in the first connecting hole; and
filling a conductive material in the first connecting hole, thus resulting in the formation of the first conductive plug, the first conductive plug connected at one end to the first connecting wire, the other end of the first conductive plug available for electrical connection to the bottom electrode of the piezoelectric vibrator, or wherein
the formation of the first connection comprising the first conductive plug and the first connecting wire on the back side of the device wafer comprises:
forming a first connecting hole by etching the device wafer from the front side thereof;
filling a conductive material in the first connecting hole, thus resulting in the formation of the first conductive plug, the first conductive plug electrically connected to the first interconnect;
thinning the device wafer from the back side thereof so that the first conductive plug is exposed; and
forming the first connecting wire on the back side of the device wafer, the first connecting wire connected at one end to the first conductive plug, the other end of the first connecting wire available for electrical connection to the bottom electrode, or wherein
the formation of the first connection comprising the first conductive plug and the first connecting wire on the back side of the device wafer comprises:
thinning the device wafer from the back side thereof and forming a first connecting hole by etching the device wafer from the back side thereof,
filling a conductive material in the first connecting hole, thus resulting in the formation of the first conductive plug, the first conductive plug electrically connected at one end to the first interconnect; and
forming the first connecting wire on the back side of the device wafer, the first connecting wire connected at one end to the other end of the first conductive plug, the other end of the first connecting wire available for electrical connection to the bottom electrode, or
wherein the bottom electrode is formed on the back side of the device wafer so as to extend beyond the piezoelectric crystal thereunder to come into electrical connection with the first conductive plug.

14-15. (canceled)

16. The method for integrating a crystal resonator with a control circuit of claim 11, wherein the second connection is formed prior to the formation of the top electrode, and wherein:
the second connection comprises a second conductive plug in the device wafer, two ends of the second conductive plug configured to be electrically connected respectively to the second interconnect and the top electrode; or
the second connection comprises a second conductive plug in the device wafer and second connecting wire on the back side of the device wafer, the second connecting wire electrically connected to one end of the second conductive plug, the second conductive plug electrically connected at the other end to the second interconnect, the second connecting wire electrically connected to the top electrode; or
the second connection comprises a second conductive plug in the device wafer and a second connecting wire on the front side of the device wafer, the second connecting wire electrically connected to one end of the second conductive plug, the second conductive plug electrically connected at the other end to the top electrode, the second connecting wire electrically connected to the second interconnect.

17. The method for integrating a crystal resonator with a control circuit of claim 16, wherein the formation of the second connection comprising the second conductive plug and the second connecting wire on the front side of the device wafer comprises:
forming a second connecting hole by etching the device wafer from the front side thereof;
filling a conductive material in the second connecting hole, thus resulting in the formation of the second conductive plug;
forming the second connecting wire on the front side of the device wafer, the second connecting wire connected to the second conductive plug and the second interconnect;
thinning the device wafer from the back side thereof so that the second conductive plug is exposed and becomes available for electrical connection to the top electrode of the piezoelectric vibrator, or wherein
the formation of the second connection comprising the second conductive plug and the second connecting wire on the front side of the device wafer comprises:
forming the second connecting wire on the front side of the device wafer, the second connecting wire electrically connected to the second interconnect;
thinning the device wafer from the back side thereof and forming a second connecting hole by etching the device wafer from the back side thereof, the second connecting hole penetrating through the device wafer so that the second connecting wire is exposed in the second connecting hole; and
filling a conductive material in the second connecting hole, thus resulting in the formation of the second conductive plug, the second conductive plug connected at one end to the second connecting wire, the other end of the second conductive plug available for electrical connection to the top electrode of the piezoelectric vibrator, or
wherein the formation of the second connection comprising the second conductive plug and the second connecting wire on the back side of the device wafer comprises:
forming a second connecting hole by etching the device wafer from the front side thereof;
filling a conductive material in the second connecting hole, thus resulting in the formation of the second conductive plug, the second conductive plug electrically connected to the second interconnect;
thinning the device wafer from the back side thereof so that the second conductive plug is exposed; and
forming the second connecting wire on the back side of the device wafer, the second connecting wire connected at one end to the second conductive plug, the other end of the second connecting wire available for electrical connection to the top electrode, or wherein
the formation of the second connection comprising the second conductive plug and the second connecting wire on the back side of the device wafer comprises:
thinning the device wafer from the back side thereof and forming a second connecting hole by etching the device wafer from the back side thereof,
filling a conductive material in the second connecting hole, thus resulting in the formation of the second conductive plug, the second conductive plug electrically connected at one end to the second interconnect; and
forming the second connecting wire on the back side of the device wafer, the second connecting wire connected at one end to the other end of the second conductive plug, the other end of the second connecting wire available for electrical connection to the top electrode.

18. (canceled)

19. The method for integrating a crystal resonator with a control circuit of claim 16, wherein the piezoelectric crystal is formed on the back side of the device wafer, and the formation of the second connection further comprises, prior to the formation of the top electrode on the device wafer:
forming a plastic encapsulation layer on the back side of the device wafer; and
forming a through hole in the plastic encapsulation layer and filling a conductive material in the through hole, thus resulting in the formation of a third conductive plug, the third conductive plug having a bottom electrically connected to the second conductive plug and having a top exposed from the plastic encapsulation layer, and
wherein the top electrode is so formed on the device wafer that it extends be-yond the piezoelectric crystal over the top of the third conductive plug, thus coming into electrical connection with the third conductive plug; or subsequent to the formation of the top electrode, an interconnecting wire is formed on the plastic encapsulation layer, the interconnecting wire extending over the top electrode at one end and over the third conductive plug at the other end, or
wherein the top electrode and the piezoelectric crystal are sequentially formed on the substrate, wherein the formation of the second connection further comprises, prior to the bonding of the device wafer and the substrate:
forming a plastic encapsulation layer on the surface of the substrate; and
forming, in the plastic encapsulation layer, a through hole in which the top electrode is exposed, and filling a conductive material in the through hole, thus resulting in the formation of a third conductive plug, the third conductive plug electrically connected at one end to the top electrode, and
wherein the device wafer and the substrate are so bonded together that the other end of the third conductive plug is electrically connected to the second conductive plug.

20. (canceled)

21. The method for integrating a crystal resonator with a control circuit of claim 1, wherein the formation of the second connecting structure comprises:
forming a contact pad on the front side of the device wafer, which has a bottom electrically connected to the control circuit and a top configured to be electrically connected to the semiconductor die, and/or
wherein the bonding of the device wafer and the substrate comprises:
applying an adhesive layer to the device wafer and/or the substrate and bonding the device wafer and the substrate together by means of the adhesive layer, and/or
wherein the substrate is bonded to the back side of the device wafer before the semiconductor die is bonded to the front side of the device wafer, or
wherein the semiconductor die is bonded to the front side of the device wafer before the substrate is bonded to the back side of the device wafer.

22-23. (canceled)

24. A structure for integrating a crystal resonator with a control circuit, comprising:
a device wafer in which the control circuit and a lower cavity are formed, the lower cavity having an opening at a back side of the device wafer;
a substrate, which is bonded to the device wafer from the back side thereof, and in which an upper cavity is formed, the upper cavity having an opening arranged in opposition to the opening of the lower cavity;
a piezoelectric vibrator comprising a top electrode, a piezoelectric crystal and a bottom electrode, the piezoelectric vibrator arranged between the device wafer and the substrate so that the lower and upper cavities are on opposing sides of the piezoelectric vibrator;
a first connecting structure configured to electrically connect the top and bottom electrodes of the piezoelectric vibrator to the control circuit;
a semiconductor die bonded to a front side of the device wafer; and
a second connecting structure configured to electrically connect the semiconductor die to the control circuit.

25. The structure for integrating a crystal resonator with a control circuit of claim 24, wherein the device wafer comprises a substrate wafer and a dielectric layer on the substrate wafer, and/or
wherein the second connecting structure comprises:
a contact pad, which has a bottom electrically connected to the control circuit and a top electrically connected to the semiconductor die.

26. The structure for integrating a crystal resonator with a control circuit of claim 24, wherein the control circuit comprises a first interconnect and a second interconnect and the first connecting structure comprises a first connection and a second connection,
the first connection connected to both the first interconnect and the bottom electrode of the piezoelectric vibrator, the second connection connected to both the second interconnect and the top electrode of the piezoelectric vibrator.

27. The structure for integrating a crystal resonator with a control circuit of claim 26, wherein the first connection comprises
a first conductive plug, which penetrates through the device wafer so as to extend to the front side of the device wafer at one end and to extend to the back side of the device wafer into electrical connection with the bottom electrode of the piezoelectric vibrator at the other end.

28. The structure for integrating a crystal resonator with a control circuit of claim 27, wherein the first connection further comprises a first connecting wire,
which is formed on the front side of the device wafer and is connected to both the first conductive plug and the first interconnect,
or which is formed on the back side of the device wafer and is connected to both the first conductive plug and the bottom electrode, and/or
wherein the bottom electrode is formed on the back side of the device wafer so to extend beyond the piezoelectric crystal into electrical connection with the first conductive plug.

29. (canceled)

30. The structure for integrating a crystal resonator with a control circuit of claim 26, wherein the second connection comprises
a second conductive plug, which penetrates through the device wafer so as to extend to the front side of the device wafer into electrical connection with the second interconnect at one end and to extend to the back side of the device wafer into electrical connection with the top electrode of the piezoelectric vibrator at the other end.

31. The structure for integrating a crystal resonator with a control circuit of claim 30, wherein the second connection further comprises a second connecting wire,
which is formed on the front side of the device wafer and is connected to both the second conductive plug and the second interconnect,
or which is formed on the back side of the device wafer and is connected to both the second conductive plug and the top electrode.

32. The structure of claim 30, wherein the second connection further comprises
a third conductive plug, which is formed on the back side of the device wafer so as to be electrically connected to the top electrode at one end and to the second conductive plug at the other end, or
wherein the second connection further comprises:
a third conductive plug formed on the back side of the device wafer, the third conductive plug having a bottom electrically connected to the second conductive plug; and
an interconnecting wire, which extends over the top electrode at one end and over the top of the third conductive plug at the other end.

33-34. (canceled)
